(19) United States
(12) Patent Application Publication
(10) Pub. No.: US 2018/0332731 A1
(43) Pub. Date: Nov. 15, 2018

(54) ELECTRICAL JUNCTION BOX

(71) Applicants: AutoNetworks Technologies, Ltd., Yokkaichi, Mie (JP); Sumitomo Wiring Systems, Ltd., Yokkaichi, Mie (JP); SUMITOMO ELECTRIC INDUSTRIES, LTD., Osaka-shi, Osaka (JP)

(72) Inventor: Yukinori Kita, Yokkaichi, Mie (JP)

(21) Appl. No.: 15/774,439

(22) PCT Filed: Nov. 21, 2016
(86) PCT No.: PCT/JP2016/084404

§ 371 Date: May 8, 2018

(30) Foreign Application Priority Data
Dec. 11, 2015 (JP) 2015-241848
Apr. 22, 2016 (JP) 2016-086055

(51) Int. Cl. H05K 7/20; H05K 1/02; H05K 1/18; H05K 7/14; H01F 27/28; H05K 5/04

(52) U.S. Cl. CPC H05K 7/2039; H05K 1/0204; H05K 1/181; H02G 3/081; H01F 27/2823; H05K 5/04; H05K 2201/1003; H05K 7/1427

(57) ABSTRACT

An electrical junction box includes a circuit assembly in which a coil assembly having a main body is mounted on a mounting surface of a circuit board, a case for accommodating the circuit assembly, and a heat sink provided on a side of the circuit board that is opposite to the mounting surface. The case has a top plate that covers the circuit assembly from the mounting surface side and is in thermal contact with the main body of the coil assembly.

### CROSS-REFERENCE TO RELATED APPLICATIONS

This application is the U.S. national stage of PCT/JP2016/084404 filed Nov. 21, 2016, which claims priority of Japanese Patent Application No. JP 2015-241848 filed Dec. 11, 2015 and Japanese Patent Application No. JP 2016-086055 filed Apr. 4, 2016.

### TECHNICAL FIELD

The technology disclosed in this specification relates to an electrical junction box.

### BACKGROUND

Conventionally known is an electrical junction box in which a circuit assembly with electronic components mounted in a conductive path of a circuit board is accommodated in a case (see JP 2003-87934A). The electronic components generate heat when current flows through them, and thus a heat dissipation plate is attached to the circuit assembly. Heat generated in the electronic components is dissipated by this heat dissipation plate.

In recent years, the density of heat generated in an electrical junction box tends to increase due to a decrease in the size of electronic components. Thus, there is a concern that heat will not be distributed sufficiently using only a heat dissipation plate.

The technology disclosed in this specification is accomplished based on the above-described circumstances, and its object is to increase the heat dissipation of an electrical junction box.

### SUMMARY

The technology disclosed in this specification relates to an electrical junction box including a circuit assembly in which an electronic component having a main body is mounted on a mounting surface of a circuit board, a case for accommodating the circuit assembly, and a heat sink provided on a side of the circuit board that is opposite to the mounting surface, in which the case has either one or both of a top plate that covers the circuit assembly from the mounting surface side and a frame portion that is in contact with the electronic component, and the top plate is in thermal contact with the main body of the electronic component.

According to the technology disclosed in this specification, heat generated in an electronic component when current flows through it is partially transmitted to the top plate that is in thermal contact with the electronic component. Heat is then dissipated from the top plate to the outside of the electrical junction box. In this manner, according to this embodiment, heat generated in an electronic component is dissipated from a case to the outside of an electrical junction box, and thus the heat dissipation of the electrical junction box can be increased, compared to an electrical junction box having only a heat sink.

The following aspects are preferable as embodiments of the technology disclosed in this specification.

It is preferable that the electronic component is a coil assembly, and an opposing surface of the main body of the coil assembly that faces the mounting surface of the circuit board is located apart from the mounting surface.

According to the above configuration, if electronic components arranged in the electrical junction box emit a large amount of heat, the emitted heat exceeds the heat dissipation capability of a heat sink in some cases. In such a case, there is a concern that heat will be reversely transmitted to the electronic components from the heat sink. In this embodiment, the main body of the coil assembly is arranged at a position distant from the circuit board, and thus it is possible to reduce the influence of heat received from the heat sink via the circuit board. Meanwhile, the top plate of the case is in thermal contact with an upper side of the main body, and thus heat generated from the coil assembly is transmitted to the case, releasing heat from the case. Accordingly, the electrical junction box has an excellent heat dissipation property.

It is preferable that the top plate is provided with a contact protrusion that protrudes toward the main body and is in contact with the main body.

According to the above-described configuration, heat can be transmitted from the coil assembly to the contact protrusion and the case (top plate) because the contact protrusion is in contact with the main body, and thus the heat dissipation of the electrical junction box can be further increased.

It is preferable that the coil assembly includes a coil obtained by winding a flat wire edgewise, both ends of the flat wire extend from the main body in a direction along the circuit board and are bent in a crank-shape, and their front ends serve as connection portions that are connected to a conductive path provided on the circuit board, and the connection portions are arranged closer to the circuit board side than a plane including the opposing surface of the main body.

According to the above-described configuration, the connection portion is arranged closer to the circuit board than the plane including the opposing surface of the main body, and thus the main body can be reliably separated from the mounting surface of the circuit board by connecting the connection portion to the conductive path of the circuit board.

The case is preferably made of metal.

According to the above-described configuration, the electrical junction box has a much better heat dissipation property, compared to configurations in which the case is made of a synthetic resin, for example.

The frame portion and the top plate are preferably in contact with each other.

According to the above-described configuration, heat generated in an electronic component when current flows through it is transmitted to the frame portion and transmitted to the top plate from the frame portion. Heat transmitted to the top plate is dissipated to the outside of the electrical junction box. This makes it possible to efficiently dissipate heat generated in an electronic component to the outside of the electrical junction box, thus, making it possible to increase the heat dissipation of the electrical junction box.

It is preferable that the top plate has a fitting protrusion that protrudes toward the electronic component and is fitted to a fitting recess provided in the frame portion, and a surface of the fitting recess that is opposite to the fitting protrusion is in contact with the electronic component.

According to the above-described configuration, heat generated in an electronic component when current flows through it is transmitted from the electronic component to the fitting recess of the frame portion. Because the fitting protrusion of the top plate is fitted to this fitting recess, heat quickly moves from the fitting recess to the fitting protrusion. Furthermore, heat transmitted from the fitting protrusion to the top plate is dissipated to the outside of the electrical junction box. This makes it possible to further increase the heat dissipation of the electrical junction box.

It is preferable that the top plate has a plurality of the fitting protrusions, and the frame portion has a plurality of the fitting recesses, another electronic component that is different from the electronic component is mounted on the mounting surface of the circuit board, and the other electronic component is arranged between the plurality of fitting protrusions and the plurality of fitting recesses.

According to the above-described configuration, heat generated in the other electronic component is transmitted to the plurality of fitting protrusions and the plurality of fitting recesses. Heat transmitted to the plurality of fitting protrusions and the plurality of fitting recesses is dissipated from the case to the outside of the electrical junction box. This makes it possible to further increase the heat dissipation of the electrical junction box.

According to the technology disclosed in this specification, it is possible to obtain an electrical junction box having an excellent heat dissipation property.

### BRIEF DESCRIPTION OF DRAWINGS

FIG. 1 is a cross-sectional view showing an electrical junction box according to Embodiment 1.

FIG. 2 is an exploded perspective view of a choke coil.

FIG. 3 is a perspective view of a coil assembly.

FIG. 4 is a cross-sectional view showing an electrical junction box according to Embodiment 2.

### DETAILED DESCRIPTION OF PREFERRED EMBODIMENTS

### Embodiment 1

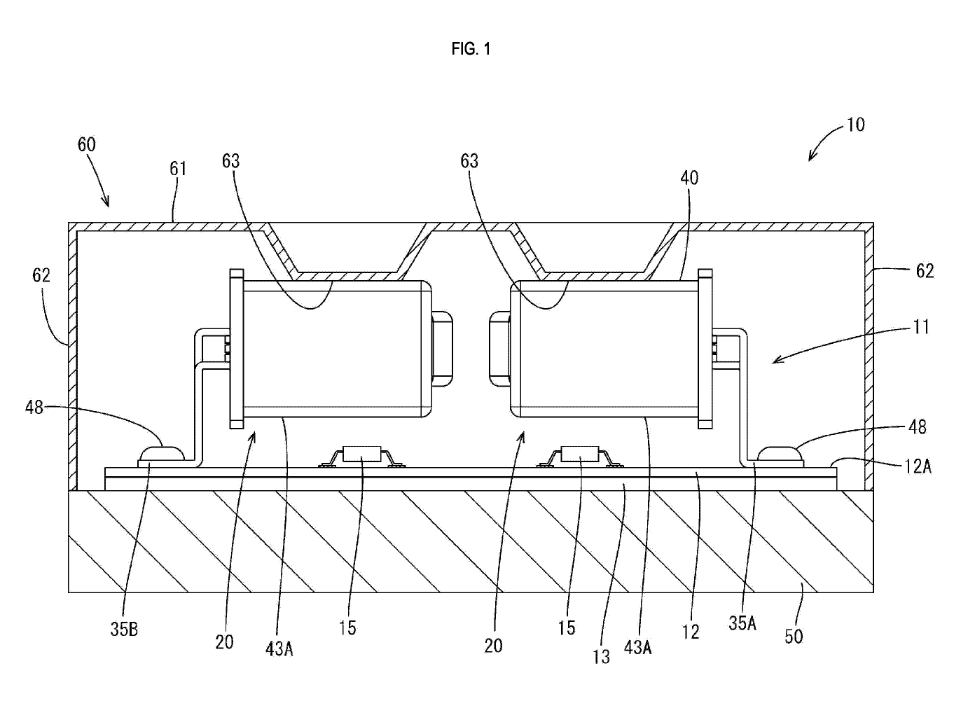

Embodiment 1 will be described with reference to FIGS. 1 to 3. An electrical junction box 10 according to the present embodiment is arranged between a power source such as a battery, and an onboard electrical component such as a lamp or a motor, and supplies and cuts off power supplied from the power source to the onboard electrical component. In the following description, “front” or “upper” refers to the upper side of FIG. 1, and “back” or “lower” refers to the lower side of FIG. 1.

### Electrical Junction Box 10

As shown in FIG. 1, the electrical junction box 10 includes a circuit assembly 11 obtained by mounting small components 15 and coil assemblies 20 (an example of an electronic component) on a circuit board 12, a heat sink 50 arranged on the back side (a lower side in FIG. 1) of the circuit board 12, and a case 60 for accommodating the circuit assembly 11.

### Circuit Assembly 11

The circuit assembly 11 includes the circuit board 12. The circuit board 12 is obtained by routing and adhering a plurality of bus bars 13 in a predetermined pattern on/to the back side of a printed wiring board provided with a conductive path (not shown) that is formed on a surface of an insulation board through printed wiring. The small components 15 and the coil assemblies 20 are mounted at predetermined positions of the circuit board 12. The small components 15 are transistors, capacitors, or the like.

Note that a surface (front side) of the circuit board 12 on which the small components 15 and the coil assemblies 20 are mounted is regarded as a mounting surface 12A.

### Coil Assembly 20

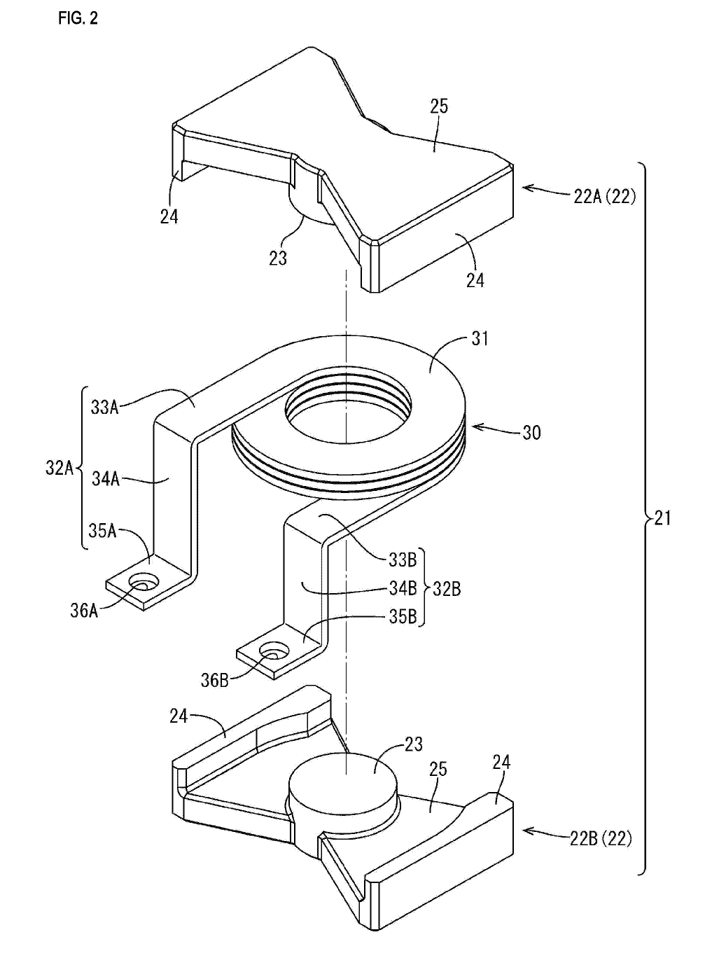

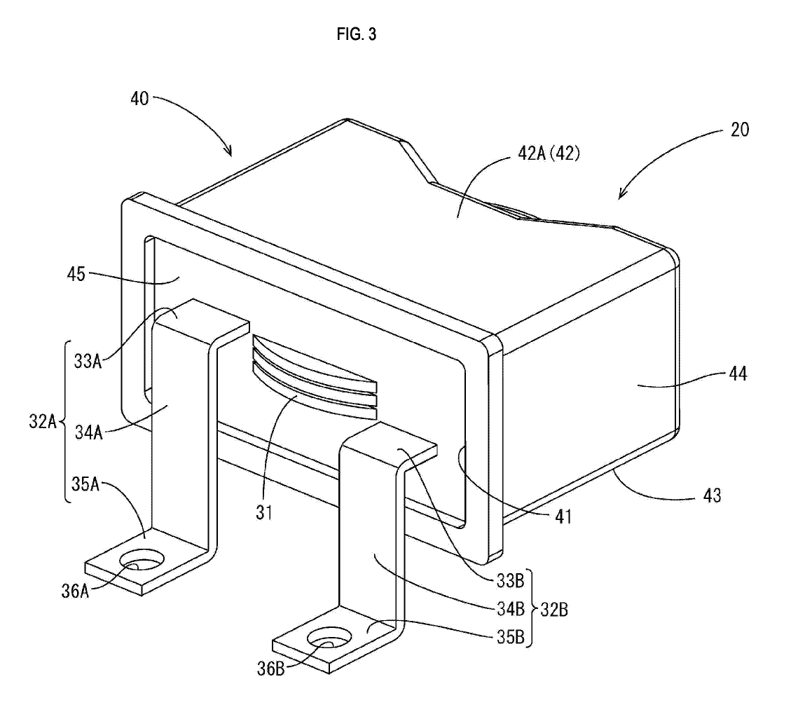

The coil assemblies 20 are obtained by accommodating magnetic cores 22 and coils 30 (corresponding to edgewise coils) obtained by winding winding wires in coil cases 40 and filling these with potting materials 45 (see FIG. 3). Hereinafter, in the following description, the terms “top”, “bottom”, “front”, and “rear” respectively refer to the up, down, the left-front, and the right-back in FIGS. 2 and 3.

The magnetic core 22 is a so-called PQ core, and as shown in FIG. 2, includes a pair of a first core 22A and a second core 22B that have the same shape that are put together. The first core 22A and the second core 22B each have a cylindrical wound portion 23 (around which a wire is wound), a pair of approximately plate-shaped legs 24 that flank the wound portion 23 on both sides and extend in parallel to each other in an axis direction of the wound portion 23, and plate-shaped connection portions 25 respectively connecting the wound portion 23 and one end portion of the pair of legs 24 to each other. The wound portion 23 and the legs 24 are made to have an equal height with respect to the connection portions 25. Also, those two side edges of the connection portions 25 that are not connected to the legs 24 are obliquely cut out from the two end portions of the legs 24 toward the wound portion 23.

The coil 30 in the present embodiment is an edgewise coil obtained by winding the flat wire edgewise and annularly. As shown in FIG. 2, the coil 30 has a shape such that both ends of a flat wire extend in parallel to each other in the same direction (frontward) from the upper end and the lower end of a winding portion 31 obtained by winding the flat wire to have an overall tubular shape, and the both ends are bent downward into a crank shape.

Hereinafter, in FIG. 2, an end extending from the upper side of the winding portion 31 is referred to as “first end portion 32A”, and an end extending from its lower side is referred to as “second end portion 32B”. Also, a part of the first end portion 32A that extends frontward from the winding portion 31 is regarded as “first extension portion 33A”, its part that is continuous with the first extension portion 33A and extends downward is regarded as “first step portion 34A”, and its front end part that is continuous with the first step portion 34A and extends frontward is regarded as “first connection portion 35A”. Also, similarly, a part of the second end portion 32B that extends frontward from the winding portion 31 is regarded as “second extension portion 33B”, its part that is continuous with the second extension portion 33B and extends downward is regarded as “second step portion 34B”, and its front end part that is continuous with the second step portion 34B and extends frontward is regarded as “second connection portion 35B”.

The first connection portion 35A and the second connection portion 35B are arranged in parallel with the first extension portion 33A and the second extension portion 33B. Also, the first connection portion 35A and the second connection portion 35B are arranged to have an equal height (be flush with each other), and are arranged below a lower edge of the winding portion 31.

Note that the first connection portion 35A and the second connection portion 35B are provided with connection holes 36A and 36B through which connection bolts 48 pass.

The coil 30 is arranged around the wound portions 23 of the pair of first core 22A and second core 22B, and accordingly, the coil 30 forms a choke coil 21 together with the magnetic core 22. As shown in FIG. 3, the choke coil 21 is accommodated in the coil case 40.

The coil case 40 is made of a synthetic resin, and as shown in FIG. 3, is constituted by an open box with an opening 41 on one side (the front side). Specifically, the coil case 40 has an upper wall 42 and a bottom wall 43 extending along the upper side and the lower side of the choke coil 21, a pair of side walls 44 extending along left and right side surfaces (legs 24) of the choke coil 21, and a rear wall extending along the back surface of the choke coil 21.

As shown in FIG. 2, the choke coil 21 is accommodated in the coil case 40 in an orientation in which the pair of first end portion 32A and second end portion 32B protrude outwardly from the opening 41. Also, the coil case 40 is filled with the potting material 45 in a state in which the choke coil 21 is accommodated in the coil case 40. Note that an epoxy resin or the like may be used as the potting material 45, for example.

In this state, both ends of the flat wire in the coil 30 (the first end portion 32A and the second end portion 32B) extend out of the coil case 40. Also, parts of the first end portion 32A and the second end portion 32B that extend from the coil case 40 (the first extension portion 33A and the second extension portion 33B) are tightly fixed by the potting material 45 such that their base ends do not move.

Also, the first connection portion 35A and the second connection portion 35B are arranged below a lower surface 43A of the bottom wall 43 of the coil case 40. The lower surface 43A of the bottom wall 43 is regarded as an opposing surface 12A that faces the mounting surface 12A of the circuit board 12.

Note that a portion of the above-described coil assembly 20, in which the coil case 40, the choke coil 21 accommodated in the coil case 40, and the potting material 45 with which the coil case 40 is filled are integrated, is referred to as “main body 46”.

As shown in FIG. 1, the above-described coil assembly 20 is conductively connected at a predetermined position on the circuit board 12.

### Heat Sink 50

The lower side of the circuit board 12 (the back surface side of the bus bar 13) is provided with the heat sink 50. The heat sink 50 is a flat plate-shaped heat dissipation member made of metal such as, for example, aluminum or an aluminum alloy that has excellent thermal conductivity, and has the function to dissipate heat generated in the circuit board 12.

An insulating sheet for achieving insulation properties between the heat sink 50 and the circuit board 12 (bus bar 13) is placed on the upper side of the heat sink 50 (not shown). The insulating sheet is adhesiveness so that it can be fixed to the bus bar 13 and the heat sink 50.

Also, the bolt holes (not shown) into which bolts 48, which will be described later, can be screwed are provided at predetermined positions of the heat sink 50.

### Case 60

The circuit board 12 that is placed on the heat sink 50 via the insulating sheet is accommodated in the case 60 (see FIG. 1). The case 60 has a substantially cuboidal box shape made by stamping and bending a galvanized steel plate (made of metal), for example, and includes a top plate 61 covering the circuit assembly 11 from the mounting surface 12A side and four side walls 62 extending downward from edges of this top plate 61.

A region of the top plate 61 that corresponds to the main body 46 of the coil assembly 20 in the state in which the circuit assembly 11 is accommodated in the case 60 is provided with contact protrusions 63 that protrude toward the main body 46 and are in contact with the upper surfaces 42A of the upper walls 42 of the main bodies 46. In the present embodiment, a pair of coil assemblies 20 are mounted on the circuit board 12, and a pair of contact protrusions 63 are also provided in correspondence with the coil assemblies 20.

### Method for Manufacturing Electrical Junction Box 10

Next, a method for manufacturing an electrical junction box 10 of the present embodiment will be described. First, a plurality of bus bars 13 are laid out and adhered in a predetermined pattern to a back side of a printed wiring board having the mounting surface 12A (front side) on which a conductive circuit (not shown) is printed through printed wiring.

Next, the small components 15 other than the coil assemblies 20 are arranged at predetermined positions on the mounting surface 12A of the circuit board 12, and are connected thereto by soldering.

Next, the circuit board 12 on which the small components 15 are mounted is placed on and fixed to a predetermined position of the upper side of the heat sink 50 via an adhesive insulating sheet (not shown). Lastly, the coil assemblies 20 are arranged at predetermined positions on the circuit board 12, and are electrically connected to the bus bars 13 by inserting the bolts 48 into the connection holes 36A and 36B of the first connection portion 35A and the second connection portion 35B and fastening (screwing) the bolts 48 to the bolt holes of the heat sink 50.

Here, both ends (the first end portion 32A and the second end portion 32B) of the flat wire of the coil 30 are led out from the coil case 40 (main body 46) in a direction along the circuit board 12 and are bent in a crank shape, their front ends (the first connection portion 35A and the second connection portion 35B) protrude downward (toward the circuit board 12) from the lower surface 43A (a lower surface of the main body 46) of the bottom wall 43 of the coil case 40, and thus the main body 46 is arranged at a distant position above the circuit board 12.

Note that “distant position ” here refers to a distance at which the main body 46 is not easily thermally influenced by the heat sink 50 via the circuit board 12, and in the present embodiment, the small components 15 are arranged (between the main body 46 and the circuit board 12) below the main body 46.

Next, the case 60 is attached and relatively fixed by a fixing means (not shown) so as to cover the integrated circuit assembly 11 and heat sink 50.

In this state, the contact protrusions 63 provided on the top plate 61 of the case 60 are in contact with the upper surface of the main body 46 of the coil assembly 20 (the upper surface 42A of the upper wall 42 of the coil case 40). In this manner, the electrical junction box 10 is completed.

### Effects of Embodiment

Next, the effects of the present embodiment will be described. The present embodiment is an electrical junction box 10 including a circuit assembly 11 in which a coil assembly 20 having a main body 46 is mounted on a mounting surface 12A of a circuit board 12, a case 60 for accommodating the circuit assembly 11, and a heat sink 50 provided on a side of the circuit board 12 that is opposite to the mounting surface 12A, and the case 60 has a top plate 61 that covers the circuit assembly 11 from the mounting surface 12A side and is in thermal contact with the main body 46 of the coil assembly 20.

According to the present embodiment, heat that is generated in the coil assemblies 20 when current flows through them is partially transmitted to the top plate 61 that is in thermal contact with the coil assemblies 20. Then, heat is dissipated from the top plate 61 to the outside of the electrical junction box 10. In this manner, according to the present embodiment, heat generated in the coil assembly 20 is dissipated from the case 60 to the outside of the electrical junction box 10, and thus the heat dissipation of the electrical junction box 10 can be increased, compared to the case where the electrical junction box 10 has only the heat sink 50.

Also, according to the present embodiment, an electronic component is the coil assembly 20, and the lower surface 43A of the main body 46 of the coil assembly 20 that faces the mounting surface 12A of the circuit board 12 is located apart from the mounting surface 12A.

If the coil assemblies 20 arranged in the electrical junction box 10 emit a large amount of heat, the emitted heat may exceed the heat dissipation capability of the heat sink 50 in some cases. In such a case, there is a concern that heat will be reversely transmitted to the coil assemblies 20 from the heat sink 50. In the present embodiment, the main bodies 46 of the coil assemblies 20 are arranged at positions distant from the circuit board 12, and thus it is possible to reduce the influence of heat received from the heat sink 50 via the circuit board 12. Meanwhile, the top plate 61 (contact protrusions 63) of the case 60 is in thermal contact with the upper surface (the upper surface 42A of the upper wall 42) of the main body 46, and thus heat generated from the coil assemblies 20 is transmitted to the case 60, and heat can be released from the case 60.

That is, even if the temperature of the heat sink 50 becomes high due to other small components 15 such as FETs, heat is inhibited from being transmitted to the coil assemblies 20, whereas heat generated in the coil assemblies 20 is released from the case 60 (top plate 61), and it is possible to efficiently release heat generated in the circuit assembly 11 using both the heat sink 50 and the case 60. Thus, the electrical junction box 10 has an excellent heat dissipation property.

Also, according to the present embodiment, the top plate 61 is provided with the contact protrusions 63. Heat can be transmitted from the coil assemblies 20 to the contact protrusions 63 and the case 60 (top plate 61) because the contact protrusions 63 are in contact with the main body 46, and thus it is possible to further increase the heat dissipation of the electrical junction box.

Also, the case 60 (top plate 61) is made of metal, and thus the electrical junction box 10 has a much better heat dissipation property, compared to configurations in which the case 60 is made of a synthetic resin, for example.

### Embodiment 2

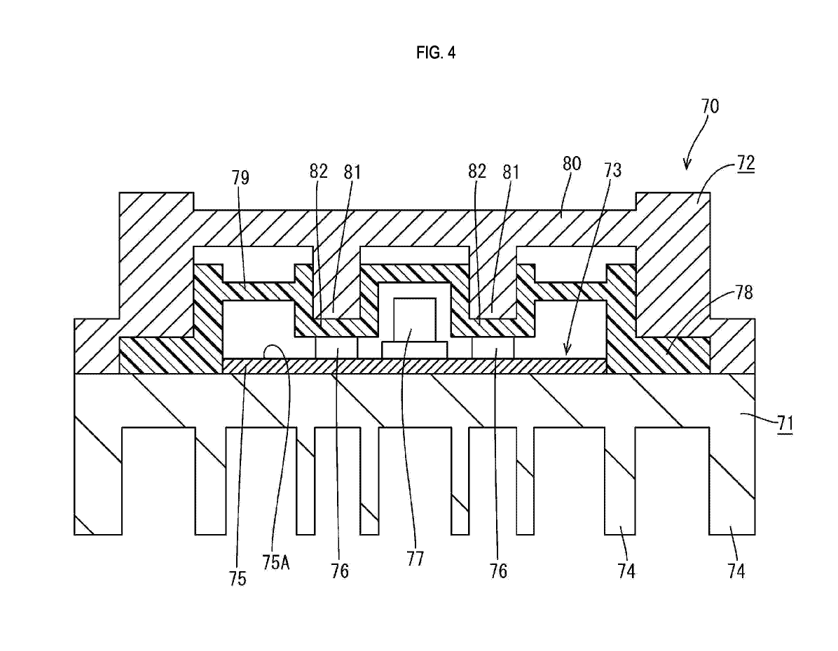

Next, an electrical junction box 70 according to Embodiment 2 will be described with reference to FIG. 4. The electrical junction box 70 includes a metal heat sink 71, a metal case 72 that covers an upper side of the heat sink 71, and a circuit assembly 73 accommodated in the case 72.

A plurality of fins 74 protrude downward from a lower side of the heat sink 71. A circuit board 75 is arranged via an insulating layer (not shown) on an upper side of the heat sink 71.

Semiconductor devices 76 (one example of electronic components) and a capacitor 77 (one example of the other electronic components) are mounted on the upper surface 75A (mounting surface) of the circuit board 75. Specifically, connection portions (not shown) of the semiconductor devices 76 and a connection portion (not shown) of the capacitor 77 are connected to a conductive path (not shown) formed on the circuit board 75 using a known method such as soldering.

A frame portion 78 made of a synthetic resin is provided inside the case 72. The frame portion 78 surrounds the circuit board 75. The frame portion 78 includes a bridge 79 that is arranged above the circuit board 75.

At least a part of the frame portion 78 is held between the case 72 and the heat sink 71. Accordingly, the frame portion 78 is thermally connected to the case 72 and the heat sink 71.

The case 72 includes a top plate 80 that covers the circuit board 75 from above. The top plate 80 covers the semiconductor devices 76 and the capacitor 77 from above (from the mounting surface side).

The top plate 80 is provided with a plurality (two in FIG. 4) of fitting protrusions 81 that are suspended downward from positions corresponding to the semiconductor devices 76 and are lined up in the horizontal direction in FIG. 4. These fitting protrusions 81 are respectively fitted from above to a plurality (two in FIG. 4) of fitting recesses 82 formed in the bridge 79 of the frame portion 78. Accordingly, the frame portion 78 and the top plate 80 are thermally connected to each other.

The lower sides of the fitting recesses 82 are in contact with the upper sides of the semiconductor devices 76 from above. The lower sides of the fitting recesses 82 and the upper sides of the semiconductor devices 76 may be in direct contact with each other, or may be in indirect contact with each other via a known heat transmission sheet, an adhesive, or an adhering agent.

The capacitor 77 is arranged between two fitting protrusions 81 and fitting recesses 82 that are lined up in the horizontal direction in FIG. 4. The capacitor 77 is arranged apart from the fitting recesses 82 in the frame portion 78. Also, the capacitor 77 is arranged apart (at a distance) from the bridge 79 in the frame portion 78.

The configurations other than the above are substantially the same as those of Embodiment 1, and thus the same members are given the same reference numerals and their redundant description will be omitted.

### Effects of Embodiment

Next, the effects of the present embodiment will be described. According to the present embodiment, the electrical junction box 70 has, in its case 72, a frame portion 78 that is in contact with semiconductor devices 76, and the frame portion 78 and the top plate 80 are in contact with each other.

According to the above-described configuration, heat generated in the semiconductor devices 76 when current flows through them is transmitted to the frame portion 78 and transmitted to the top plate 80 from the frame portion 78. Heat transmitted to the top plate 80 is dissipated to the outside of the electrical junction box 70. Accordingly, it is possible to efficiently dissipate heat generated in the semiconductor devices 76 to the outside of the electrical junction box 70, and thus to increase the heat dissipation of the electrical junction box 70.

Also, according to the present embodiment, the top plate 80 has the fitting protrusions 81 that protrude toward the semiconductor devices 76 and are fitted to the fitting recesses 82 provided in the frame portion 78, and surfaces of the fitting recesses 82 that are opposite to the fitting protrusions 81 are in contact with the semiconductor devices 76.

Heat generated in the semiconductor devices 76 when current flows through them is transmitted to the fitting recesses 82 of the frame portion 78 from the semiconductor devices 76. Since the fitting protrusions 81 of the top plate 80 are fitted to the fitting recesses 82, heat readily moves from the fitting recesses 82 to the fitting protrusions 81. Heat transmitted from the fitting protrusions 81 to the top plate 80 is dissipated to the outside of the electrical junction box 70. Accordingly, it is possible to further increase the heat dissipation of the electrical junction box 70.

Also, according to the present embodiment, the top plate 80 has the plurality of fitting protrusions 81, the frame portion 78 has the plurality of fitting recesses 82, the capacitor 77 that is different from the electronic components is mounted on the mounting surface of the circuit board 75, and the capacitor 77 is arranged between the plurality of fitting protrusions 81 and the plurality of fitting recesses 82.

According to the above-described configuration, heat generated in the capacitor 77 is transmitted to the plurality of fitting protrusions 81 and the plurality of fitting recesses 82. Heat transmitted to the plurality of fitting protrusions 81 and the plurality of fitting recesses 82 is dissipated from the case 72 to the outside of the electrical junction box 70. Accordingly, it is possible to further increase the heat dissipation of the electrical junction box 70.

### Other Embodiments

The technology disclosed in this specification is not merely limited to the embodiments described above using the foregoing description and drawings, and embodiments such as the following are also encompassed in the technical scope of the present disclosure.

Although the contact protrusions 63 are provided on the top plate 61 in Embodiment 1, the contact protrusions 63 do not necessarily have to be provided.

Although the contact protrusions 63 are provided by bending a metal plate material in Embodiment 1, a configuration may also be adopted in which protrusions are provided on a flat plate by protruding these portions. A configuration may also be adopted in which a plurality of contact protrusions are in contact with one coil assembly.

Although the case 60 is made of metal in Embodiment 1, the case 60 may also be made of a synthetic resin. Alternatively, a configuration may also be adopted in which a case is constituted by a member separate from a cover portion and a frame body, only the cover portion is made of metal, and the frame body is made of a synthetic resin.

The coil assembly 20 is not limited to Embodiment 1, and may also have another configuration. For example, a configuration may also be adopted in which a connection portion is directly led out from the lower side of the main body, in short, the configuration need only be such that when a coil assembly is mounted on a circuit board, its main body is arranged at a position distant from the mounting surface 12A at which the main body is not easily thermally influenced by a heat sink.

Although the coil assembly 20 is connected to the circuit board 12 by fastening a bolt in Embodiment 1, a configuration may also be adopted in which the coil assembly 20 is connected thereto by solder.

Although in Embodiment 1, a configuration is adopted in which the main body 46 of the coil assembly 20 can be supported by tightly fixing the main body 46 of the coil assembly 20 to the circuit board 12 by fastening, with bolts, both end portions 32A and 32B (connection portions 35A and 35B) of the coil 30 that are led out from the main body 46, and thereby the main body 46 is arranged at a position distant from the mounting surface 12A, a configuration may also be adopted in which the main body 46 is arranged at a position distant from the mounting surface 12A by providing other means, such as providing a separate support portion for supporting the main body 46, for example.

Although an example in which an edgewise coil is used as the coil 30 was described in Embodiment 1, a mode may also be adopted in which another type of coil is used.

Although a configuration in which both end portions 32A and 32B of the coil 30 extend from the winding portion 31 in the same direction is adopted in Embodiment 1, both end portions do not necessarily extend in the same direction, and a configuration may also be adopted in which both end portions extend in directions that intersect each other, or in which they extend in opposite directions.

Although an example in which a PQ core is used as the magnetic core 22 was described in Embodiment 1, other types of cores such as an EI core, an EE core, an EER core, and an EPC core may also be used as the magnetic core.

Although the circuit board 12 and the heat sink 50 are relatively fixed using an adhesive insulating sheet in Embodiment 1, a configuration in which they are adhered to each other using an insulating adhesive, or a configuration in which they are fixed to each other by screwing may be adopted, for example.

1. An electrical junction box comprising:
a circuit assembly in which an electronic component having a main body is mounted on a mounting surface of a circuit board;
a case for accommodating the circuit assembly; and
a heat sink provided on a side of the circuit board that is opposite to the mounting surface,
wherein the case has either one or both of a top plate that covers the circuit assembly from the mounting surface side and a frame portion that is in contact with the electronic component, and
the top plate is in thermal contact with the main body of the electronic component.

2. The electrical junction box according to claim 1,
wherein the electronic component is a coil assembly, and
an opposing surface of the main body of the coil assembly that faces the mounting surface of the circuit board is located apart from the mounting surface.

3. The electrical junction box according to claim 2,
wherein the top plate is provided with a contact protrusion that protrudes toward the main body and is in contact with the main body.

4. The electrical junction box according to claim 2,
wherein the coil assembly includes a coil obtained by winding a flat wire edgewise, both ends of the flat wire extend from the main body in a direction along the circuit board and are bent in a crank shape, and their front ends serve as connection portions that are connected to a conductive path provided on the circuit board, and
the connection portions are arranged closer to the circuit board side than a plane including the opposing surface of the main body.

5. The electrical junction box according to claim 1,
wherein the case is made of metal.

6. The electrical junction box according to claim 1,
wherein the frame portion and the top plate are in contact with each other.

7. The electrical junction box according to claim 6,
wherein the top plate has a fitting protrusion that protrudes toward the electronic component and is fitted to a fitting recess provided in the frame portion, and
a surface of the fitting recess that is opposite to the fitting protrusion is in contact with the electronic component.

8. The electrical junction box according to claim 7,
wherein the top plate has a plurality of the fitting protrusions, and the frame portion has a plurality of the fitting recesses,
another electronic component that is different from the electronic component is mounted on the mounting surface of the circuit board, and
the other electronic component is arranged between the plurality of fitting protrusions and the plurality of fitting recesses.

9. The electrical junction box according to claim 3, wherein the coil assembly includes a coil obtained by winding a flat wire edgewise, both ends of the flat wire extend from the main body in a direction along the circuit board and are bent in a crank shape, and their front ends serve as connection portions that are connected to a conductive path provided on the circuit board, and
the connection portions are arranged closer to the circuit board side than a plane including the opposing surface of the main body.

10. The electrical junction box according to claim 2, wherein the case is made of metal.

11. The electrical junction box according to claim 3, wherein the case is made of metal.

12. The electrical junction box according to claim 4, wherein the case is made of metal.

13. The electrical junction box according to claim 2, wherein the frame portion and the top plate are in contact with each other.

14. The electrical junction box according to claim 3, wherein the frame portion and the top plate are in contact with each other.

15. The electrical junction box according to claim 4, wherein the frame portion and the top plate are in contact with each other.

16. The electrical junction box according to claim 5, wherein the frame portion and the top plate are in contact with each ot
